(19) United States
(12) Patent Application Publication
(10) Pub. No.: US 2017/0092473 A1
(43) Pub. Date: Mar. 30, 2017

(54) IN-SITU PLASMA CLEANING OF PROCESS CHAMBER ELECTROSTATIC ELEMENTS HAVING VARIED GEOMETRIES

(71) Applicant: Varian Semiconductor Equipment Associates, Inc., Gloucester, MA (US)

(72) Inventors: William Davis Lee, Newburyport, MA (US); Kevin Anglin, Somerville, MA (US); Peter Kurunczi, Cambridge, MA (US); Ryan Downey, Gloucester, MA (US); Jay T. Scheuer, Rowley, MA (US); Alexandre Likhanskii, Malden, MA (US)

(21) Appl. No.: 14/867,442

(22) Filed: Sep. 28, 2015

(51) Int. Cl. H01J 37/32; H01L 21/265; H01L 21/67; H01J 37/317

(52) U.S. Cl. CPC H01J 37/32862; H01J 37/3171; H01J 37/32889; H01L 21/265; H01L 21/67069; H01L 21/67034; H01J 2237/006; H01J 2237/022; H01J 2237/303; H01J 2237/31705; H01J 2237/335

(57) ABSTRACT

Provided herein are approaches for in-situ plasma cleaning of one or more components of an ion implantation system. In one approach, the component may include a beam-line component having a conductive beam optic, the beam optic having a varied geometry configured to generate a concentrated electric field proximate the beam optic. The system further includes a power supply for supplying a first voltage and first current to the component during a processing mode and a second voltage and second current to the component during a cleaning mode. The second voltage and current may be applied to the one or more beam optics, in parallel, to selectively (e.g., individually) generate plasma in an area corresponding to the concentrated electric field. By providing custom-shaped ion beam optics, plasma density is strategically enhanced in areas where surface contamination is most prevalent, thus improving cleaning efficiency and minimizing tool down time.

### FIELD OF THE DISCLOSURE

The disclosure relates generally to techniques for manufacturing electronic devices, and more particularly, to techniques for improving the performance and extending the lifetime of components within a processing chamber.

### BACKGROUND OF THE DISCLOSURE

Ion implantation is a process of introducing dopants or impurities into a substrate via bombardment. In semiconductor manufacturing, the dopants are introduced to alter electrical, optical, or mechanical properties. For example, dopants may be introduced into an intrinsic semiconductor substrate to alter the type and level of conductivity of the substrate. In manufacturing an integrated circuit (IC), a precise doping profile provides improved IC performance. To achieve a particular doping profile, one or more dopants may be implanted in the form of ions in various doses and various energy levels.

Ion implantation systems may comprise an ion source and a series of beam-line components. The ion source may comprise a chamber where ions are generated. The ion source may also comprise a power source and an extraction electrode assembly disposed near the chamber. The beam-line components, may include, for example, a mass analyzer, a first acceleration or deceleration stage, a collimator, and a second acceleration or deceleration stage. Much like a series of optical lenses for manipulating a light beam, the beam-line components can filter, focus, and manipulate ions or ion beam having particular species, shape, energy, and/or other qualities. The ion beam passes through the beam-line components and may be directed toward a substrate mounted on a platen or clamp. The substrate may be moved in one or more dimensions (e.g., translate, rotate, and tilt) by an apparatus, sometimes referred to as a roplat.

The ion implanter system generates a stable, well-defined ion beam for a variety of different ion species and extraction voltages. After several hours of operation using source gases (such as AsH₃, PH₃, BF₃, and other species), beam constituents eventually create deposits on beam optics. Beam optics within a line-of-sight of the wafer also become coated with residues from the wafer, including Si and photoresist compounds. These residues build up on the beam-line components, causing spikes in the DC potentials during operation (e.g., in the case of electrically biased components). Eventually the residues flake off, causing an increased likelihood of particulate contamination on the wafer.

One way to prevent the effect of the material accumulation is to intermittently replace beam-line components of the ion implanter system. Alternatively, beam-line components may be manually cleaned. Yet, manually cleaning entails powering down the ion source, and releasing the vacuum within the system. After replacing or cleaning the beam-line components, the system is then evacuated and powered to reach an operational condition. Accordingly, these maintenance processes may be very time consuming. In addition, the beam-line component is not used during the maintenance processes. As such, frequent maintenance processes may decrease the time available for IC production, thus increasing overall manufacturing cost.

### SUMMARY

In view of the foregoing, provided herein are systems and methods for in-situ plasma cleaning of ion implantation system components (e.g., ion beam optics), wherein the in-situ plasma cleaning may be performed over a short time, avoiding the need to vent and/or manually clean the ion beam optics. Moreover, provided herein are systems and methods for in-situ plasma cleaning of one or more ion beam optics having varied geometries configured to generate a concentrated electric field, wherein a plasma is locally generated in an area corresponding to the concentrated electric field to facilitate targeted etching to just those surfaces in need of cleaning. By providing custom-shaped ion beam optics, plasma density is strategically enhanced in areas where surface contamination is most prevalent, thus improving cleaning efficiency and minimizing tool down time (TDT).

An exemplary ion implantation system in accordance with the present disclosure may include a component within a chamber of the ion implantation system, the component including a conductive beam optic having a varied geometry configured to generate a concentrated electric field proximate the conductive beam optic. The ion implantation system may further include a power supply in communication with the component, the power supply configured to supply a voltage and a current to the component during a cleaning mode, wherein the voltage and the current are applied to the conductive beam optic to generate a plasma around the conductive beam optic in an area corresponding to the concentrated electric field. The ion implantation system may further include an etchant gas supplied to the component to enable etching of the conductive beam optic.

An exemplary system in accordance with the present disclosure may include an energy purity module (EPM) including a chamber for generation of a plasma, wherein the EPM includes a plurality of conductive beam optics disposed along an ion beam-line, and wherein one or more of the plurality of conductive beam optics has a varied geometry selected to generate a concentrated electric field proximate the one or more of the plurality of conductive beam optics. The system may further include a power supply in communication with the EPM, the power supply configured to supply a first voltage and a first current to the plurality of conductive beam optics during a processing mode and a second voltage and a second voltage and a second current to the plurality of conductive beam optics during a cleaning mode, wherein the second voltage and the second current are supplied to the one or more of the plurality of conductive beam optics to generate a plasma around the one or more of the plurality of conductive beam optics in an area corresponding to the concentrated electric field. The system may further include an etchant gas supplied to the EPM to enable etching of the one or more of the plurality of conductive beam optics.

An exemplary method in accordance with the present disclosure may include providing a component of a process chamber, the process chamber operable for generating a plasma, wherein the component includes a conductive beam optic having a varied geometry configured to generate a concentrated electric field proximate the conductive beam optic. The method may further include supplying a first voltage and a first current to the component during a processing mode. The method may further include supplying a second voltage and a second current to the component during a cleaning mode, wherein the second voltage and the second current are applied to a conductive beam optic of the component to generate a plasma around the conductive beam optic in an area corresponding to the concentrated electric field.

### BRIEF DESCRIPTION OF THE DRAWINGS

FIG. 1 is a schematic view illustrating an ion implantation system in accordance with embodiments of the present disclosure.

FIG. 2A is a semi-transparent isometric view illustrating a component of the ion implantation system shown in FIG. 1 in accordance with embodiments of the present disclosure.

FIG. 2B is a semi-transparent isometric view illustrating a component of the ion implantation system shown in FIG. 1 in accordance with embodiments of the present disclosure.

FIG. 3 is a side cross-sectional view illustrating the component of the ion implantation system shown in FIGS. 2A-B in a processing mode in accordance with embodiments of the present disclosure.

FIG. 4 is a side cross-sectional view illustrating build-up of surface contamination along the component of the ion implantation system shown in FIGS. 2A-B in accordance with embodiments of the present disclosure.

FIGS. 5A-C are illustrations of ion beam optics of the component having various geometric features in accordance with embodiments of the present disclosure.

FIG. 6 is a side cross-sectional view illustrating generation of plasma within the component of the ion implantation system shown in FIGS. 2A-B in a cleaning mode in accordance with embodiments of the present disclosure.

FIG. 7 is a flowchart illustrating an exemplary method in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

A system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

For the sake of convenience and clarity, terms such as “top,” “bottom,” “upper,” “lower,” “vertical,” “horizontal,” “lateral,” and “longitudinal” will be used herein to describe the relative placement and orientation of these components and their constituent parts, with respect to the geometry and orientation of a component of a semiconductor manufacturing device as appearing in the figures. The terminology will include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

As stated above, provided herein are approaches for in-situ plasma cleaning of one or more components of an ion implantation system. In one approach, the component may include a beam-line component having a conductive beam optic, the beam optic having a varied geometry configured to generate a concentrated electric field proximate the beam optic. The system further includes a power supply for supplying a first voltage and first current to the component during a processing mode and a second voltage and second current to the component during a cleaning mode. The second voltage and current may be applied to the one or more beam optics, in parallel, to selectively (e.g., individually) generate plasma in an area corresponding to the concentrated electric field. By providing custom-shaped ion beam optics, plasma density is strategically enhanced in areas where surface contamination is most prevalent, thus improving cleaning efficiency and minimizing TDT.

Furthermore, approaches herein provide improvements for in-situ plasma cleaning of conductive elements in an ion beam-line. Ion optical elements in an ion beam-line may alter the direction or energy of the ions traveling through them, leading to unwanted ions or neutral atoms ending up on component surfaces. This can lead to undesirable coating, or surface contamination. This surface contamination can lead to flaking and generation of particles, and altering the performance of the ion optic or beamline element. Additionally, photoresist, sputtered and back-spattered material from either the wafer or other regions impacted by the ion beam can lead to similar undesirable coating of beamline elements.

Embodiments herein further provide isolating an element or elements in the beamline, flowing a gas or gases to form etchants or etchant chemistries (Ar, NF₃, O₂, etc.), and applying bias to these elements, either with DC or RF potentials, to clean them. The ratio of these gases can be varied to optimally clean based on the recipe set, run by the tool, (e.g. boron heavy recipe sets may be cleaned better with high fluorine while carbon heavy recipe sets may clean more optimally with oxygen rich chemistries).

Furthermore, embodiments herein provide switching to a cleaning mode of operation, while avoiding major modifications to the existing tool design. In cleaning mode, the beam-line element(s) can be driven in parallel using the same DC power supply or by switching to an RF power supply to avoid disruptive arcing during the cleaning cycle. A suitable high voltage relay switch may be configured for switching between modes, thus avoiding having to manually switch power cables.

In some embodiments, an etchant gas can be flowed into a chamber from an existing source or from a different source, with minimal effects on tool architecture. The gas ratio can be varied to optimize the chemistry and cleaning efficiency depending on the composition of the optics residues. For example, fluorine-based plasmas have been commonly used to etch beam components containing B, P, and As, while oxygen-based plasmas are known to readily etch photoresist. Other well-referenced etch chemistries may also be used. In another approach, by adding Ar or other heavy species to the plasma mixture, increased ion bombardment (sputtering) can help further improve the removal rate of unwanted residues through a chemically enhanced ion beam etching mechanism. Plasma or ion bombardment also provokes heating of the surfaces to aid chemical etch rates and help volatilize by-products from the surface.

As stated above, approaches herein recognize the influence one or more geometric features (e.g., cross-sectional shapes or surface features) have on plasma generation and, thus, cleaning performance. More specifically, surface regions with non-uniform, strategically varied geometric features cause the electric field to be concentrated in certain areas, and more diffuse in others. Matching higher concentration electric field areas with the regions of higher contamination deposition, and lower concentration electric field areas with the regions of lower contamination deposition, maximizes efficiency of the subsequent cleaning process.

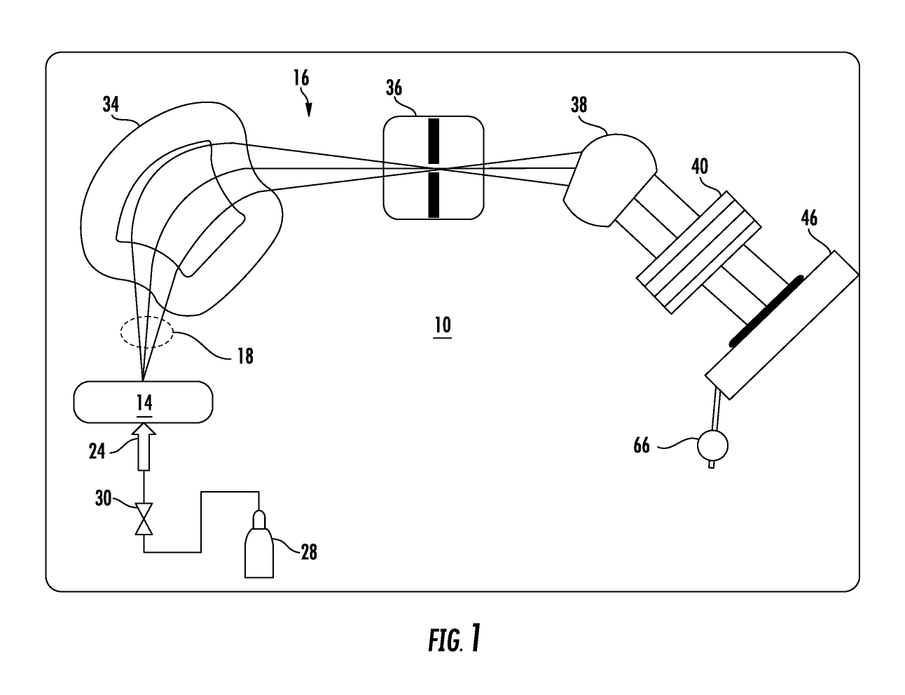

Referring now to FIG. 1, an exemplary embodiment demonstrating a system 10 for performing in-situ plasma cleaning of one or more components of an ion implantation system in accordance with the present disclosure is shown. The ion implantation system (hereinafter “system”) 10 represents a process chamber containing, among other components, an ion source 14 for producing an ion beam 18, an ion implanter, and a series of beam-line components. The ion source 14 may comprise a chamber for receiving a flow of gas 24 and generates ions. The ion source 14 may also comprise a power source and an extraction electrode assembly disposed near the chamber. The beam-line components 16 may include, for example, a mass analyzer 34, a first acceleration or deceleration stage 36, a collimator 38, and an energy purity module (EPM) 40 corresponding to a second acceleration or deceleration stage. Although described hereinafter with respect to the EPM 40 of the beam-line components 16 for the sake of explanation, the embodiments described herein for in-situ plasma cleaning are also applicable to different/additional components of the system 10.

In exemplary embodiments, the beam-line components 16 may filter, focus, and manipulate ions or the ion beam 18 to have a particular species, shape, energy, and/or other qualities. The ion beam 18 passing through the beam-line components 16 may be directed toward a substrate mounted on a platen or clamp within a process chamber 46. The substrate may be moved in one or more dimensions (e.g., translate, rotate, and tilt).

As shown, there may be one or more feed sources 28 operable with the chamber of the ion source 14. In some embodiments, material provided from the feed source 28 may include source material and/or additional material. The source material may contain dopant species introduced into the substrate in the form of ions. Meanwhile, the additional material may include diluent, introduced into the ion source chamber of the ion source 14 along with the source material to dilute the concentration of the source material in the chamber of the ion source 14. The additional material may also include a cleaning agent (e.g., an etchant gas) introduced into the chamber of the ion source 14 and transported within the system 10 to clean one or more of the beam-line components 16.

In various embodiments, different species may be used as the source and/or the additional material. Examples of the source and/or additional material may include atomic or molecular species containing boron (B), carbon (C), oxygen (O), germanium (Ge), phosphorus (P), arsenic (As), silicon (Si), helium (He), neon (Ne), argon (Ar), krypton (Kr), nitrogen (N), hydrogen (H), fluorine (F), and chlorine (Cl). Those of ordinary skill in the art will recognize the above listed species are non-limiting, and other atomic or molecular species may also be used. Depending on the application(s), the species may be used as the dopants or the additional material. In particular, one species used as the dopants in one application may be used as the additional material in another application, or vice-versa.

In exemplary embodiments, the source and/or additional material is provided into the ion source chamber of the ion source 14 in gaseous or vapor form. If the source and/or additional material is in non-gaseous or non-vapor form, a vaporizer (not shown) may be provided near the feed source 28 to convert the material into gaseous or vapor form. To control the amount and the rate the source and/or the additional material is provided into the system 10, a flowrate controller 30 may be provided.

The EPM 40 is a beam-line component configured to independently control deflection, deceleration, and focus of the ion beam 18. In one embodiment, the EPM 40 is a vertical electrostatic energy filter (VEEF) or electrostatic filter (EF). As will be described in greater detail below, the EPM 40 may include an electrode configuration comprising a set of upper electrodes disposed above the ion beam 18 and a set of lower electrodes disposed below the ion beam 18. The set of upper electrodes and the set of lower electrodes may be stationary and have fixed positions. A difference in potentials between the set of upper electrodes and the set of lower electrodes may also be varied along the central ion beam trajectory to reflect an energy of the ion beam at various point along the central ion beam trajectory for independently controlling deflection, deceleration, and/or focus of an ion beam.

During normal operation, some of the ions traversing through the EPM 40 exchange charge with background neutrals. These may be neutrals of the residual gas in the tool, for example nitrogen and water, or neutral products evolving off a wafer during ion implant. These products can be varied in composition, and thus allow for complicated chemical interactions. During the charge exchange process, the formerly neutral atoms become charged and accelerate towards the negatively biased electrodes in the EPM 40 as “slow” ions resulting in surface contamination on the electrodes. Oftentimes surface contamination is not uniformly deposited, thus making discriminately cleaning just those contaminated surfaces advantageous.

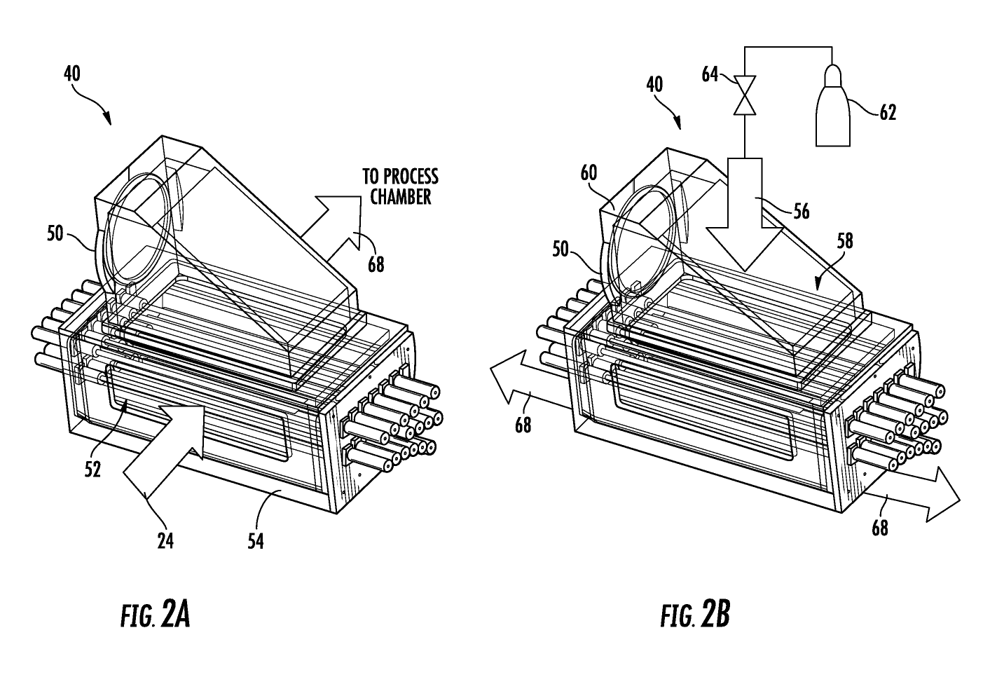

Referring now to FIGS. 2A-B, the EPM 40 according to exemplary embodiments will be described in greater detail. As shown, the EPM 40 includes an EPM chamber 50 extending above and partially encasing EPM 40. The EPM chamber 50 is configured to receive a gas and generate a plasma therein. In one embodiment, as shown in FIG. 2A, the EPM chamber 50 may receive a flow of the gas 24 (FIG. 1) from the ion source 14 at a gas inlet 52 through a sidewall 54. In another embodiment, as shown in FIG. 2B, the EPM chamber 50 may receive a flow of gas 56 at a gas inlet 58 through a top section 60 of the EPM chamber 50. The gas 56 may be supplied from a supplementary gas source 62 separate from the flow of gas 24 from the ion source 14. In this embodiment, an injection rate of the gas 56 into the EPM chamber 50 may be controlled by a flow controller 64 (e.g., a valve).

EPM 40 further operates with one or more vacuum pumps 66 (FIG. 1) to adjust a pressure of the EPM chamber 50. In exemplary embodiments, the vacuum pump 66 is coupled to the process chamber 46, and pressure is adjusted within the EPM chamber 50 through one or more flow paths 68. In another embodiment, the EPM 40 may include one or more additional pumps more directly coupled to the EPM chamber 50.

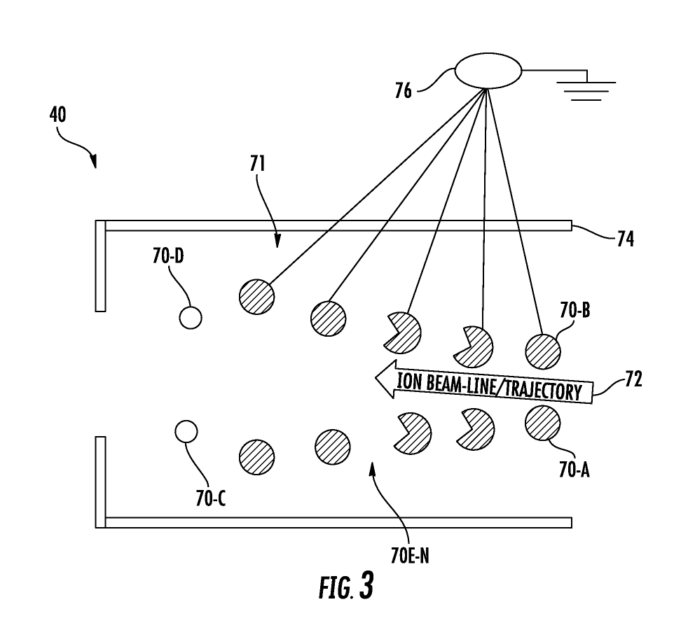

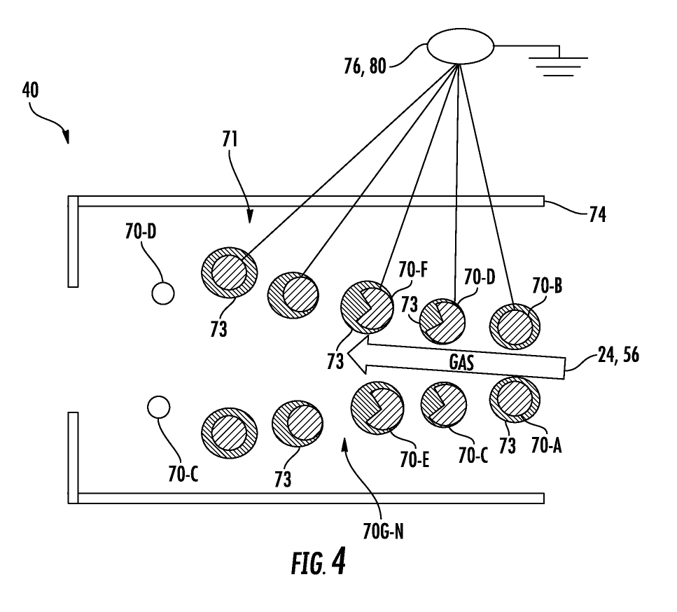

Referring now to FIGS. 3-4, an exemplary embodiment demonstrating the structure and operation of the EPM 40 in accordance with the present disclosure is shown. The EPM 40 includes one or more conductive beam optics 70A-N including a plurality of graphite electrode rods disposed along an ion beam-line/trajectory 72, as shown. In this embodiment, the conductive beam optics 70A-N are arranged in a symmetrical configuration, wherein the conductive beam optics 70A-B represent a set of entrance electrodes, the conductive beam optics 70C-D represent a set of exit electrodes, and the remaining beam optics 70E-N represent several sets of suppression/focusing electrodes. As shown, each set of electrode pairs provides a space/opening to allow the ion beam (e.g., a ribbon beam) to pass therethrough. In exemplary embodiments, the conductive beam optics 70A-N are provided in a housing 74. As described above, the vacuum pump 66 may be directly or indirectly connected to the housing 74 for adjusting a pressure of an environment 71 therein.

In exemplary embodiments, the conductive beam optics 70A-N include pairs of conductive pieces electrically coupled to one another. Alternatively, the conductive beam optics 70A-N may be a series of unitary structures each including an aperture for the ion beam to pass therethrough. In the embodiment shown, upper and lower portions of each electrode pair may have different potentials (e.g., in separate conductive pieces) in order to deflect the ion beam passing therethrough. Although the conductive beam optics 70A-N are depicted as seven (7) pairs (e.g., with five (5) sets of suppression/focusing electrodes), a different number of elements (or electrodes) may be utilized. For example, the configuration of conductive beam optics 70A-N may utilize a range of three (3) to ten (10) electrode sets.

In some embodiments, the ion beam passing through the electrodes along the ion beam-line 72 may include boron or other elements. Electrostatic focusing of the ion beam may be achieved by using several thin electrodes (e.g., the suppression/focusing electrodes of conductive beam optics 70E-N) to control grading of potential along the ion beam-line 72. In the configuration of conductive beam optics 70A-N shown, high deceleration ratios may also be provided. As a result, use of input ion beams may be used in an energy range to enable higher quality beams, even for very low energy output beams. In one non-limiting example, as the ion beam passes through the electrodes of the conductive beam optics 70A-N, the ion beam may be decelerated from 6 keV to 0.2 keV and deflected at 15°. In this non-limiting example, the energy ratio may be 30/1.

As noted above, one cause of degradation to the system 10 (FIG. 1) may be excessive accumulation of deposits or by-products generated by the beam constituents during use. For example, deposits may accumulate on the conductive beam optics 70A-N of the EPM 40, as well as on other components of the system 10, shown in FIG. 4 as a layer of surface contamination 73. In some embodiments, this accumulation of material may be more severe, e.g., when carborane, SiF₄ or GeF₄ is used as the source material.

Formation of the layer of surface contamination 73 may be non-uniform between beam optics, and/or non-uniform in different areas along a perimeter of each individual beam optic. For example, the layer of surface contamination 73 extends around the perimeter of conductive beam optics 70A and 70B, while the layer of surface contamination 73 along the conductive beam optics 70C-E is formed more prominently on a downstream side relative to the flow of the beam-line 72. Therefore, to increase the density and localization of the plasma within the EPM 40 to target these highly concentrated areas of the layer of surface contamination 73, one or more of the conductive beam optics (e.g., conductive beam optics 70C-E) have a varied geometry configured to generate a concentrated electric field proximate a surface of the conductive beam optics 70C-E.

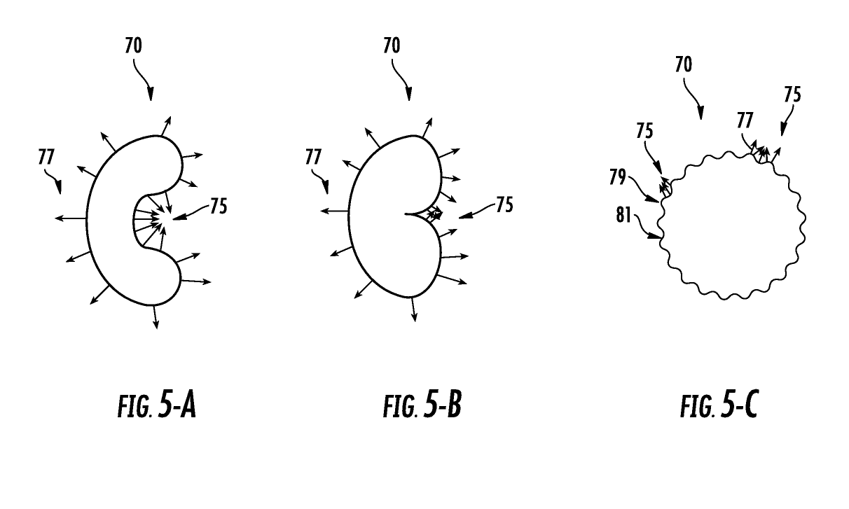

For example, as shown in FIGS. 5A-C, multiple geometries may be selected to generate a local, concentrated electric field 75 proximate the conductive beam optic 70. As shown, the concentrated electric field 75 may comprise a plurality of electrical charges emitted normal to a surface of the conductive beam optic 70. By providing surface regions/features with different curvatures or angles, an electric field 77 of the conductive beam optic 70 may converge in certain areas (e.g., concentrated electric field 75), and diverge in other areas surrounding the conductive beam optic 70. In exemplary embodiments, the concentrated electric field 75 extends a distance approximately 1-2 radii of the surface feature away from the surface of the conductive beam optic 70, thus keeping the ion beam-line 72 (FIGS. 3-4) uniform to preserve the ion beam optics.

As shown, the conductive beam optic 70 may be a beam-line electrostatic element having one or more optic shapes with surfaces containing multiple radii of curvature and/or optic shapes having a combination of concave and convex surfaces. In some embodiments, the beam-line electrostatic element may be an electrode rod having one or more geometric features, including, although not limited to: a lemniscate cross-section (FIG. 5A), a limacon cross-section (FIG. 5B), a circular cross-section combined with an exterior surface profile including a plurality of ridges 79 and indentations 81 (FIG. 5C), a kidney-shaped cross-section (not shown), an elliptical cross-section (not shown), a fluted cross-section (not shown), or virtually any other cross-section resulting in one or more non-uniform surface features to influence an electric field in proximity thereto. The conductive beam optic 70 generates a concentrated electric field 75 to produce a localized plasma when powered, as will be described in further detail below. By recognizing surface contamination patterns within the EPM 40, the shape of the electrostatic element 70 can be strategically selected, thus optimizing the initial direction/concentration of the electric field 77.

Referring again to FIGS. 3-4, the system 10 of the present embodiment may operate in two modes: a processing mode and a cleaning mode. During the processing mode, the system 10 may operate normally to produce the ion beam 18. During the cleaning mode, the EPM 40, or any other component of the system 10, such as beam-line components 16, may be in situ cleaned.

More specifically, during the processing mode, a power supply 76 (e.g., a DC power supply) supplies a first voltage and a first current to the EPM 40. The voltage/current is supplied to conductive beam optics 70A-N to generate a plasma within the EPM chamber 50 (FIGS. 2A-B). In various embodiments, the voltage and current provided by the power supply 76 may be constant or varied. In one embodiment, the conductive beam optics 70A-N are held at a series of DC potentials from 0.1 keV-100 keV.

The EPM 40 may then be switched from the processing mode to the cleaning mode. To accomplish this, the system 10 may include a relay switch (not shown) for switching between the processing mode and the cleaning mode so as to avoid having to manually switch power cables. In one embodiment, switching from the processing mode to the cleaning mode is performed automatically, for example, in the case a predetermined threshold (e.g., a set number of beam glitches) is achieved. In another embodiment, the switching can be triggered by an operator.

During the cleaning mode, a second voltage and a second current are supplied to the conductive beam optics 70A-N of the EPM 40. In one embodiment, the conductive beam optics 70A-N may be electrically driven in parallel (e.g., individually) or in series to enable uniform and/or independent cleaning thereof. The second voltage and the second current may be supplied by the DC power supply 76, or by a radio frequency (RF) power supply 80. Switching from the DC power supply 76 of the processing mode to the RF power supply 80 during the cleaning mode may minimize the chance disruptive arcing occurs during the cleaning cycle.

In exemplary embodiments, the EPM 40 may be in situ cleaned during the cleaning mode. To accomplish this, an etchant gas (e.g., gas 24, 56) may be introduced into the EPM 40 at a selected flow/injection rate. For example, the etchant gas may be introduced at a flow rate of approximately 25 standard cubic centimeters per minute (SCCM) to approximately 200 SCCM. In one embodiment, the etchant gas may be introduced at approximately 50 SCCM to approximately 100 SCCM to maintain high pressure flow around the conductive beam optics 70A-N.

Various species may be introduced as the cleaning agent of the etchant gas. The cleaning agent may be atomic or molecular species containing chemically reactive species. Such species, when ionized, may chemically react with the deposits accumulated on one or more of the conductive beam optics 70A-N. Although a cleaning agent with chemically reactive species will be described herein, the present disclosure does not preclude utilizing chemically inert species. In another embodiment, the cleaning agent may contain heavy atomic species to form ions with high atomic mass units (amu) when ionized. Non-limiting examples of the cleaning agent may include atomic or molecular species containing H, He, N, O, F, Ne, Cl, Ar, Kr, and Xe, or a combination thereof. In one embodiment, NF₃, O₂, or a mixture of Ar and F₂, or a combination thereof, may be used as the cleaning agent.

The composition of the etchant gas can be chosen to optimize chemical etching based on a composition of the deposit(s) formed on the conductive beam optics 70A-N. For example, fluorine-based plasmas may be used to etch beam components containing B, P, and As, while oxygen-based plasmas may be used to etch photoresist materials. In one embodiment, adding Ar or other heavy species to the plasma mixture increases ion bombardment, resulting in an improved removal rate of the deposit(s) from the conductive beam optics 70A-N when using a chemically enhanced ion sputtering process. Plasma or ion bombardment also provokes heating of the surfaces to aid chemical etch rates and to help agitate the deposit(s) from the surface of the conductive beam optics 70A-N.

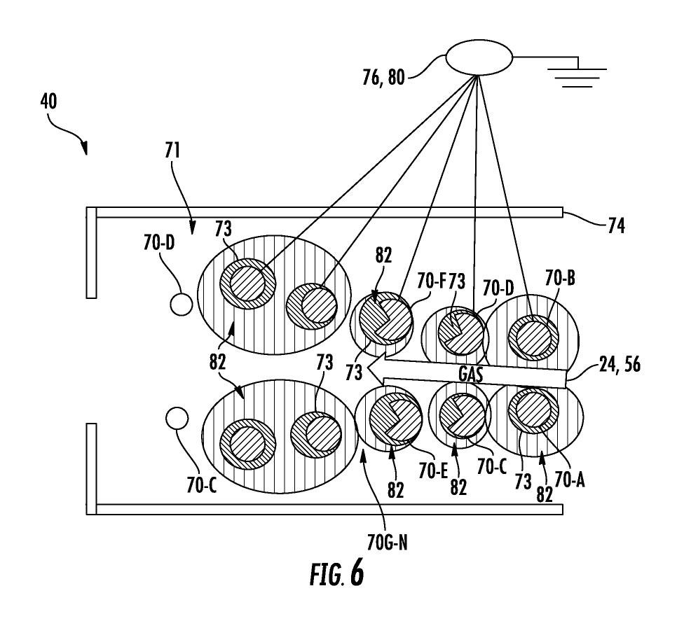

Referring now to FIG. 6, generation of the plasma will be described in greater detail. As shown, a plasma 82 is generated within the EPM 40, and concentrates near one or more of the conductive beam optics 70A-N. In the present embodiment, the plasma 82 may be created in the volume defined by the housing 74 by providing continuous or pulsed AC/DC voltage to the graphite electrodes of one or more of the conductive beam optics 70A-N. For example, approximately 400 V to 1 kV at approximately 1 A to approximately 5 A of current may be supplied to the conductive beam optics 70A-N using the DC power supply 76 or the RF power supply 80. The power may be in the form of AC voltage or pulsed DC voltage to the conductive beam optics 70A-N. As stated above, the conductive beam optics 70A-N may be driven in parallel to enable independent and selective generation of the plasma 82.

In exemplary embodiments, a density and localization of the plasma 82 within the EPM 40 is greatest surrounding those conductive beam optics having a varied geometry, such as conductive beam optics 70C-F. More specifically, the plasma 82 is localized around the conductive beam optics 70C-F in an area corresponding to the concentrated electric fields 75 (FIGS. 5A-C) due to a higher concentration of electrons, resulting in a spatially smaller and denser plasma 82 formed in proximity to the conductive beam optics 70C-F.

In exemplary embodiments, the plasma 82 may be generated proximate the highly concentrated areas of the non-uniform layer of surface contamination 73 formed on the conductive beam conductive beam optics 70C-F. For example, as shown in FIG. 6, a plasma footprint surrounding the conductive beam optics 70C-F more closely corresponds to the location(s) of the layer of surface contamination 73 than a plasma footprint surrounding the conductive beam optics 70G-N. Thus, a more targeted and effective plasma cleaning may be achieved.

Selective plasma generation is advantageous to minimize the impact of harmful radicals (e.g., fluorine) to other parts of the EPM 40, in order to prevent etching and damaging of heavy metal (e.g., steel) parts. In some embodiments, a higher flow rate through the EPM 40 can allow for faster replacement of etch by-products with fresh reactants, producing a more efficient clean process.

Still furthermore, by concentrating the plasma 82 near one or more of the conductive beam optics 70A-N according to geometric features, and by supplying the etchant gas to the EPM 40 at an optimized flow rate, the conductive beam optics 70A-N may be efficiently cleaned. For example, chemically reactive radicals contained in the plasma 82 may remove the layer of surface contaminants 73 accumulated on the surface of one of the conductive beam optics, 70E-N, via chemical reaction. In an exemplary embodiment, the conductive beam optics 70E-N are graphite electrode rods containing contaminants such as Si, Phosphorus, and photoresist. The layer of surface contaminants 73 are removed by the cleaning process, resulting in conductive beam optics similar to the conductive beam optics 70A-N depicted in FIG. 3.

In some embodiments, the ions in the plasma 82 may remove the layer of surface contaminants 73 via an ion sputtering process. The heat generated from the plasma 82 may also enhance the cleaning process as the deposits accumulated on the conductive beam optics 70A-N may be removed by the heat or may become more volatile with increased temperature. For example, as described above, the conductive beam optics 70A-N may be provided with a voltage of between 400 and 1000V at a current of between 1 to 5 amps. Thus, up to approximately 5 kW of heat may be generated. By providing highly reactive and/or heavy cleaning species, and generating the plasma 82 near the conductive beam optics 70A-N, effective plasma cleaning may be performed. As noted above, a high flow rate of the cleaning materials introduced into the EPM 40 may enhance the cleaning process.

In another embodiment, a pressure within the EPM 40 may be increased to further localize the plasma 82. Specifically, by increasing the pressure set point for the cleaning process, either by increasing the gas injection rate or reducing the pump rate to the EPM 40, the plasma 82 is further localized around those conductive beam optics 70A-N receiving a voltage/current.

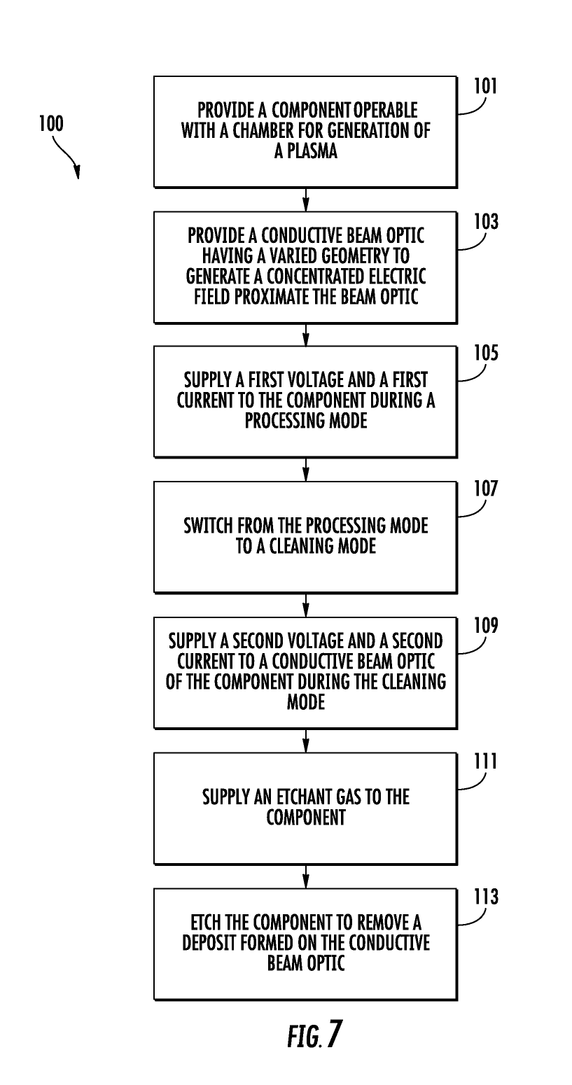

Referring now to FIG. 7, a flow diagram illustrating an exemplary method 100 for in-situ plasma cleaning one or more components of the ion implantation system in accordance with the present disclosure is shown. The method 100 will be described in conjunction with the representations shown in FIGS. 1-6.

Method 100 includes providing a component of a process chamber, as shown in block 101. In some embodiments, the component is a beam-line component, such as an energy purity module (EPM).

Method 100 further includes providing a conductive beam optic having a varied geometry configured to generate a concentrated electric field proximate the conductive beam optic, as shown in block 103. In some embodiments, the component includes a plurality of conductive beam optics. In some embodiments, the plurality of conductive beam optics includes a plurality of electrode rods having one or more of the following geometric features: a lemniscate cross-section, a limacon cross-section, a kidney-shaped cross-section, and a circular cross-section with an exterior surface profile including a plurality of indentations. In some embodiments, each conductive beam optic includes a non-uniform layer of surface contamination formed thereon, the non-uniform layer of contamination having one or more regions of relatively higher concentration.

Method 100 further includes supplying a first voltage and a first current to the component during a processing mode, as shown in block 105. In some embodiments, a first voltage and a first current are supplied by a direct current (DC) power supply.

The method 100 further includes switching from the processing mode to a cleaning mode, as shown in block 107. In some embodiments, the method 100 includes automatically switching from the processing mode to the cleaning mode in the case a predetermined threshold is achieved, e.g., a maximum acceptable number of beam glitches.

Method 100 further includes supplying a second voltage and a second current to the component during a cleaning mode, as shown in block 109. In some embodiments, the second voltage and the second current are applied to the conductive beam optic of the component to generate a plasma around the conductive beam optic in an area corresponding to the concentrated electric field. In some embodiments, the plasma generated proximate the one or more regions of the non-uniform surface contamination has a relatively higher density. In some embodiments, the second voltage and the second current are supplied from a direct current (DC) power supply or a radio frequency (RF) power supply.

Method 100 further includes supplying an etchant gas to the beam-line component to enable etching of the plurality of conductive beam optics, as shown in block 111. In some embodiments, an injection rate of the etchant gas is adjusted. In some embodiments, a composition of the etchant gas is selected to optimize etching of the component based on a composition of the deposit formed on a surface of the component.

Method 100 further includes etching the component to remove a deposit formed on the conductive beam optic during the processing mode, as shown in block 113. In some embodiments, the conductive beam optic is etched using an ion sputtering process.

In view of the foregoing, at least the following advantages are achieved by the embodiments disclosed herein. Firstly, the plasma cleaning may be performed over a short time, avoiding the need to vent and/or manually clean the component. Secondly, during in-situ plasma cleaning, the plasma density is greater surrounding those components, and those portions of each component, to be cleaned, thus reducing unintended etching to other surfaces of the beam-line and/or the system.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implantation system, comprising:
a component within a chamber of the ion implantation system, the component including a conductive beam optic having a varied geometry configured to generate a concentrated electric field proximate the conductive beam optic;
a power supply in communication with the component, the power supply configured to supply a voltage and a current to the component during a cleaning mode, wherein the voltage and the current are applied to the conductive beam optic to generate a plasma around the conductive beam optic in an area corresponding to the concentrated electric field; and
an etchant gas supplied to the component to enable etching of the conductive beam optic.

2. The ion implantation system of claim 1, the power supply configured to supply a first voltage and a first current to the component during a processing mode.

3. The ion implantation system of claim 1, the voltage and the current supplied from one of the following: a direct current (DC) power supply, and a radio frequency (RF) power supply.

4. The ion implantation system of claim 1, the conductive beam optic including a non-uniform layer of surface contamination formed thereon, the non-uniform layer of surface contamination having one or more regions of relatively higher concentration, wherein plasma generated proximate the one or more regions of relatively higher concentration has a relatively higher density.

5. The ion implantation system of claim 1, wherein the varied geometry includes one or more of the following geometric features: a lemniscate cross-section, a limacon cross-section, a kidney-shaped cross-section, an elliptical cross-section, a fluted cross-section, and a circular cross-section with an exterior surface profile including a plurality of indentations.

6. The ion implantation system of claim 1, further comprising a plurality of conductive beam optics.

7. The ion implantation system of claim 1, the component comprising an energy purity module.

8. A system, comprising:
an energy purity module (EPM) including a chamber for generation of a plasma, wherein the EPM includes a plurality of conductive beam optics disposed along an ion beam-line, and wherein one or more of the plurality of conductive beam optics has a varied geometry selected to generate a concentrated electric field proximate the one or more of the plurality of conductive beam optics;
a power supply in communication with the EPM, the power supply configured to supply a first voltage and a first current to the plurality of conductive beam optics during a processing mode and a second voltage and a second voltage and a second current to the plurality of conductive beam optics during a cleaning mode, wherein the second voltage and the second current are supplied to the one or more of the plurality of conductive beam optics to generate a plasma around the one or more of the plurality of conductive beam optics in an area corresponding to the concentrated electric field; and
an etchant gas supplied to the EPM to enable etching of the one or more of the plurality of conductive beam optics.

9. The system of claim 8, wherein the plurality of conductive beam optics comprises a plurality of electrode rods having one or more of the following geometric features: a lemniscate cross-section, a limacon cross-section, a kidney-shaped cross-section, an elliptical cross-section, a fluted cross-section, and a circular cross-section with an exterior surface profile including a plurality of indentations.

10. The system of claim 8, the first voltage and the first current supplied by a direct current (DC) power supply, and the second voltage and the second current supplied by one of the following: a DC power supply and a radio frequency (RF) power supply.

11. The system of claim 8, the one or more of the plurality of conductive beam optics including a non-uniform layer of surface contamination formed thereon, the non-uniform layer of surface contamination having one or more regions of relatively higher concentration, wherein plasma generated proximate the one or more regions of relatively higher concentration has a relatively higher density.

12. A method comprising:
providing a component of a process chamber, the process chamber operable for generating a plasma, wherein the component includes a conductive beam optic having a varied geometry configured to generate a concentrated electric field proximate the conductive beam optic;
supplying a first voltage and a first current to the component during a processing mode; and
supplying a second voltage and a second current to the component during a cleaning mode, wherein the second voltage and the second current are applied to a conductive beam optic of the component to generate a plasma around the conductive beam optic in an area corresponding to the concentrated electric field.

13. The method of claim 12, further comprising supplying an etchant gas to the component to enable etching of the conductive beam optic.

14. The method of claim 12, further comprising etching, during the cleaning mode, a non-uniform layer of surface contamination formed on the conductive beam optic.

15. The method of claim 14, further comprising generating the plasma proximate one or more regions of a relatively higher concentration of the non-uniform layer of surface contamination formed on the conductive beam optic.

16. The method of claim 12, wherein the conductive beam optic comprises an electrode rod having one or more of the following geometric features: a lemniscate cross-section, a limacon cross-section, a kidney-shaped cross-section, an elliptical cross-section, a fluted cross-section, and a circular cross-section with an exterior surface profile including a plurality of indentations.

17. The method of claim 13, further comprising adjusting an injection rate of the etchant gas.

18. The method according to claim 12, further comprising adjusting a pressure of an environment of the component.

19. The method according to claim 12, further comprising switching from the processing mode to the cleaning mode, wherein the first voltage and the first current are supplied by a direct current (DC) power supply, and wherein the second voltage and the second current are supplied by one of the following: a DC power supply, and a radio frequency (RF) power supply.

20. The method according to claim 19, further comprising automatically switching from the processing mode to the cleaning mode upon reaching a predetermined threshold.
